(19) United States
(12) Patent Application Publication
(10) Pub. No.: US 2024/0244863 A1
(43) Pub. Date: Jul. 18, 2024

(54) DISPLAY DEVICE

(71) Applicant: Samsung Display Co., LTD., Yongin-si, Gyeonggi-do (KR)

(72) Inventor: SEUNGUK NOH, Yongin-si, Gyeonggi-do (KR)

(21) Appl. No.: 18/513,734

(22) Filed: Nov. 20, 2023

(30) Foreign Application Priority Data
Jan. 17, 2023 (KR) 10-2023-0006786

(51) Int. Cl. H10K 50/115; H10K 59/122

(52) U.S. Cl. CPC H10K 50/115; H10K 59/122

(57) ABSTRACT

A display device includes: a substrate including a first pixel area, a second pixel area adjacent to the first pixel area, and a non-light emitting area surrounding the first pixel area and the second pixel area; a first electrode disposed in a portion overlapping the first pixel area on the substrate; a second electrode disposed in a portion overlapping the second pixel area on the substrate; a pixel defining layer disposed in a portion overlapping the non-light emitting area on the substrate and defining at least one opening; and a resin layer filling the opening.

This application claims priority to Korean Patent Application No. 10-2023-0006786, filed on Jan. 17, 2023, and all the benefits accruing therefrom under 35 U.S.C. § 119, the content of which in its entirety is herein incorporated by reference.

### BACKGROUND

### 1. Technical Field

Embodiments relate to a display device.

### 2. Description of the Related Art

With the development of information technology, an importance of a display device, which is a connection medium between a user and information, is emerging. Accordingly, a use of display device such as liquid crystal display device, organic light emitting display device, plasma display device, and quantum dot light emitting display device is increasing.

There is a desire for a method for improving performance of the quantum dot light emitting display device using quantum dots as a light emitting body.

### SUMMARY

Embodiments provide a display device with improved display quality.

A display device according to an embodiment includes: a substrate including a first pixel area, a second pixel area adjacent to the first pixel area, and a non-light emitting area surrounding the first pixel area and the second pixel area; a first electrode disposed in a portion overlapping the first pixel area on the substrate; a second electrode disposed in a portion overlapping the second pixel area on the substrate; a third electrode disposed on the first electrode and the second electrode and defining at least one opening in a portion overlapping the non-light emitting area; and a resin layer filling the opening.

In an embodiment, the resin layer may include at least one selected from a group consisting of organic acid, inorganic acid and peroxide.

In an embodiment, the organic acid may include at least one selected from a group consisting of acrylic acid, acetic acid, formic acid, propionic acid, butyric acid, isobutyric acid, valeric acid, ethyl methyl acetic acid, trimethyl acetic acid, succinic acid, adipic acid, citric acid, oxalic acid, lactic acid, tartaric acid, malic acid, ascorbic acid, and malonic acid.

In an embodiment, the inorganic acid may include at least one selected from a group consisting of sulfuric acid, hydrochloric acid, and nitric acid.

In an embodiment, the third electrode may be continuously disposed over the first pixel area, the second pixel area, and the non-light emitting area.

In an embodiment, the display device may further include: a first light emitting layer disposed between the first electrode and the third electrode; and a second light emitting layer disposed between the second electrode and the third electrode.

In an embodiment, each of the first light emitting layer and the second light emitting layer may include a quantum dot.

In an embodiment, the display device may further include: a first electronic auxiliary layer disposed between the first light emitting layer and the third electrode; and a second electron auxiliary layer disposed between the second light emitting layer and the third electrode.

In an embodiment, each of the first electron auxiliary layer and the second electron auxiliary layer may include a plurality of nanoparticles.

In an embodiment, each of the plurality of nanoparticles may include a metal oxide.

A display device according to another embodiment includes: a substrate including a first pixel area, a second pixel area adjacent to the first pixel area, and a non-light emitting area surrounding the first pixel area and the second pixel area; a first electrode disposed in a portion overlapping the first pixel area on the substrate; a second electrode disposed in a portion overlapping the second pixel area on the substrate; a pixel defining layer disposed in a portion overlapping the non-light emitting area on the substrate and defining at least one opening therein; and a resin layer filling the opening.

In an embodiment, the resin layer may include at least one selected from a group consisting of organic acid, inorganic acid and peroxide.

In an embodiment, the organic acid may include at least one selected from a group consisting of acrylic acid, acetic acid, formic acid, propionic acid, butyric acid, isobutyric acid, valeric acid, ethyl methyl acetic acid, trimethyl acetic acid, succinic acid, adipic acid, citric acid, oxalic acid, lactic acid, tartaric acid, malic acid, ascorbic acid, and malonic acid.

In an embodiment, the inorganic acid may include at least one selected from a group consisting of sulfuric acid, hydrochloric acid, and nitric acid.

In an embodiment, the display device may further include a third electrode disposed on the first electrode, the second electrode, and the pixel defining layer.

In an embodiment, the display device may further include: a first light emitting layer disposed between the first electrode and the third electrode; and a second light emitting layer disposed between the second electrode and the third electrode.

In an embodiment, each of the first light emitting layer and the second light emitting layer may include a quantum dot.

In an embodiment, the display device may further include: a first electronic auxiliary layer disposed between the first light emitting layer and the third electrode; and a second electron auxiliary layer disposed between the second light emitting layer and the third electrode.

In an embodiment, each of the first electron auxiliary layer and the second electron auxiliary layer includes a plurality of nanoparticles.

In an embodiment, each of the plurality of nanoparticles includes a metal oxide.

A display device according to an embodiment may include: a substrate including a first pixel area, a second pixel area adjacent to the first pixel area, and a non-light emitting area surrounding the first pixel area and the second pixel area; a first electrode disposed in a portion overlapping the first pixel area on the substrate; a second electrode disposed in a portion overlapping the second pixel area on the substrate; a third electrode disposed on the first electrode and the second electrode and defining at least one opening in a portion overlapping the non-light emitting area; and a resin layer filling the opening.

In order to improve light emitting efficiency and life of the display device, a resin layer of supplying acid may be applied on a light emitting element. This may be referred to as a positive aging method (or a positive aging effect). Since a plurality of openings are formed at a place that does not overlap pixel areas, the resin layer may be relatively uniformly applied to entire areas including a center of the display device.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to an embodiment.

FIG. 2 is a schematic cross-sectional view of the display device of FIG. 1 cut along line I-I′.

FIG. 3 is a schematic enlarged cross-sectional view illustrating an area A of FIG. 2.

FIGS. 4, 5, 6, and 7 are schematic cross-sectional views illustrating a method of manufacturing the display device of FIG. 2.

FIGS. 8 and 9 are schematic plan views illustrating the display device of FIG. 1.

FIG. 10 is a schematic cross-sectional view illustrating a display device according to another embodiment.

FIG. 11 is a schematic enlarged cross-sectional view illustrating an area B of FIG. 10.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, display devices in accordance with embodiments will be described in more detail with reference to the accompanying drawings. The same reference numerals are used for the same components in the drawings, and redundant descriptions of the same components will be omitted.

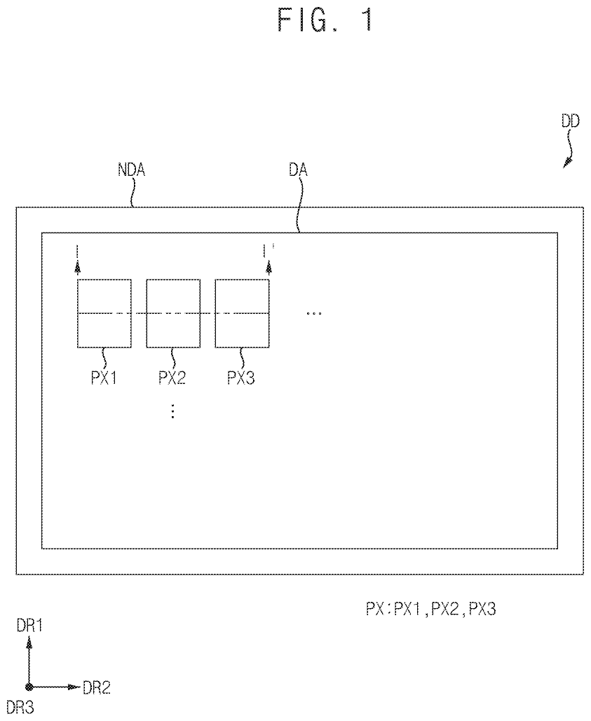

FIG. 1 is a schematic plan view illustrating a display device according to an embodiment. As used herein, the “plan view” is a view in a third direction DR3.

Referring to FIG. 1, a display device DD according to an embodiment may include a display area DA and a non-display area NDA.

A plurality of pixel areas PX may be disposed in the display area DA. The plurality of pixel areas PX may include a first pixel area PX1, a second pixel area PX2, and a third pixel area PX3. Each of the first pixel area PX1, the second pixel area PX2, and the third pixel area PX3 may refer to an area in which light emitted from light emitting elements is emitted to outside of the display device DD.

In an embodiment, for example, the first pixel area PX1 may emit first light, the second pixel area PX2 may emit second light, and the third pixel area PX3 may emit third light. In an embodiment, the first light may be red light, the second light may be green light, and the third light may be blue light. However, the present disclosure is not limited thereto. In another embodiment, for example, the plurality of pixel areas PX may be combined to emit yellow, cyan, and magenta light.

The plurality of pixel areas PX may emit light of four or more colors. In an embodiment, for example, the plurality of pixel areas PX may be combined to emit at least one of yellow, turquoise, and deep red light in addition to red, green, and blue light. In addition, the plurality of pixel areas PX may be combined to further emit white light.

The plurality of pixel areas PX may be repeatedly arranged along a first direction DR1 and a second direction DR2 intersecting the first direction DR1 on a plane (e.g., in a plan view). In an embodiment, for example, the second pixel area PX2 may be adjacent to the first pixel area PX1. Specifically, the second pixel area PX2 may be adjacent to the first pixel area PX1 in the second direction DR2. In addition, the third pixel area PX3 may be adjacent to the second pixel area PX2 in the second direction DR2.

The non-display area NDA may be disposed around the display area DA. In an embodiment, for example, the non-display area NDA may surround at least a portion of the display area DA. A driving unit may be disposed in the non-display area NDA. The driving unit may provide a signal or a voltage to the plurality of pixel areas PX. In an embodiment, for example, the driving unit may include a data driving unit, a gate driving unit, or the like.

The non-display area NDA may not display an image. [0047] the first direction DR1 and the second direction DR2 intersecting the first direction DR1 may be defined. In addition, a third direction DR3 perpendicular to a plane formed by the first direction DR1 and the second direction DR2 may be defined.

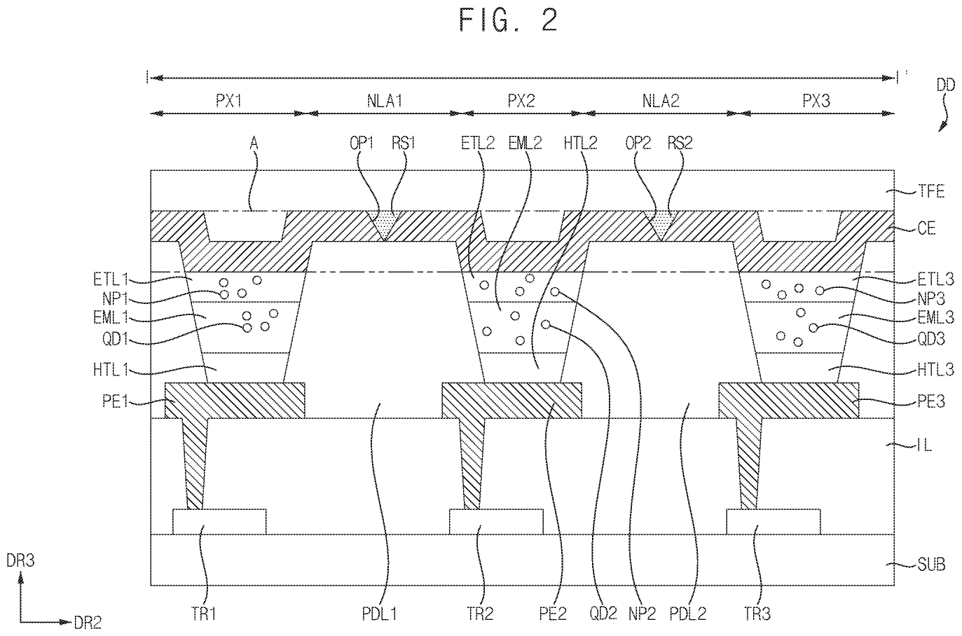

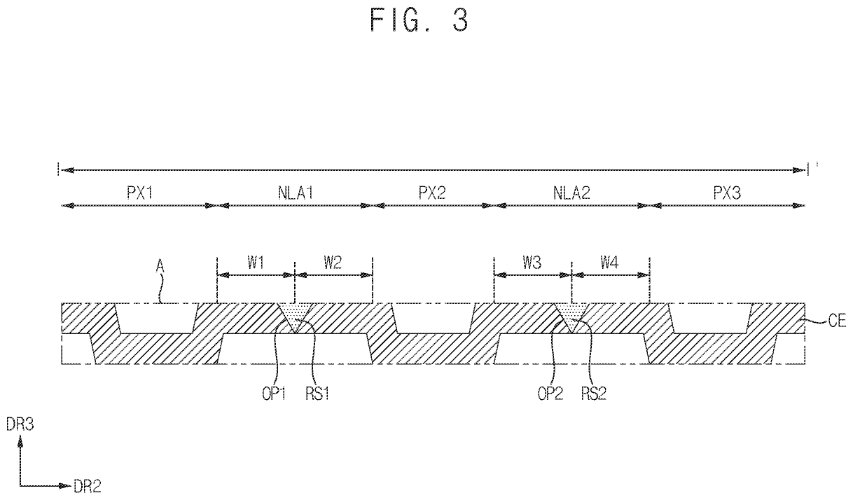

FIG. 2 is a schematic cross-sectional view of the display device of FIG. 1 cut along line I-I′. FIG. 3 is a schematic enlarged cross-sectional view illustrating an area A of FIG. 2.

Referring to FIGS. 2 and 3, the display device DD according to an embodiment may include a substrate SUB, an insulating structure IL, a first transistor TR1, a second transistor TR2, a third transistors TR3, a first pixel electrode PE1, a second pixel electrode PE2, a third pixel electrode PE3, a first hole auxiliary layer HTL1, a second hole auxiliary layer HTL2, a third hole auxiliary layer HTL3, a first light emitting layer EML1, a second light emitting layer EML2, a third light emitting layer EML3, a first electron auxiliary layer ETL1, a second electron auxiliary layer ELT2, a third electron auxiliary layer ETL3, first quantum dots QD1, second quantum dots QD2, third quantum dots QD3, first nanoparticles NP1, second nanoparticles NP2, third nanoparticles NP3, a common electrode CE, a first resin layer RS1, and a second resin layer RS2, a first pixel defining layer PDL1, and a second pixel defining layer PDL2.

The substrate SUB may include a transparent material or an opaque material. The substrate SUB may be formed of a transparent resin substrate. Examples of the transparent resin substrate may include a polyimide substrate. In this case, the polyimide substrate may include a first organic layer, a first barrier layer, a second organic layer, or the like.

Alternatively, the substrate SUB may include a quartz substrate, a synthetic quartz substrate, a calcium fluoride substrate, a fluorine-doped quartz substrate, a soda lime substrate, a non-alkali glass substrate, or the like. These materials may be used alone or in combination with each other.

The first transistor TR1, the second transistor TR2, and the third transistors TR3 may be disposed on the substrate SUB. Specifically, the first transistor TR1 may overlap the first pixel area PXT. In addition, the second transistor TR2 may overlap the second pixel area PX2.

In addition, the third transistor TR3 may overlap the third pixel area PX3.

In an embodiment, for example, each of the first transistor TR1, the second transistor TR2, and the third transistor TR3 may include amorphous silicon, polycrystalline silicon, or metal oxide semiconductor.

In an embodiment, the metal oxide semiconductor may include a binary compound (“ABₓ”), a ternary compound (“ABₓC_{y}”), a tetragonal compound (“ABₓC_{y}D_{z}”), or the like containing indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like.

In an embodiment, for example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), indium gallium zinc oxide (“IGZO”), or the like. These materials may be used alone or in combination with each other.

The insulating structure IL may be disposed on the substrate SUB. The insulating structure IL may cover the first transistor TR1, the second transistor TR2, and the third transistor TR3. The insulating structure IL may include at least one inorganic insulating layer and at least one organic insulating layer.

In an embodiment, for example, the inorganic insulating layer may include silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

In addition, the organic insulating layer may include photoresist, polyacryl-based resin, polyimide-based resin, polyamide-based resin, siloxane-based resin, acrylic-based resin, epoxy-based resin, or the like. These materials may be used alone or in combination with each other.

The first pixel electrode PET, the second pixel electrode PE2, and the third pixel electrode PE3 may be disposed on the insulating structure IL. The first pixel electrode PET may overlap the first pixel area PX1. In addition, the second pixel electrode PE2 may overlap the second pixel area PX2. In addition, the third pixel electrode PE3 may overlap the third pixel area PX3.

The first pixel electrode PET may be connected to the first transistor TR1 through a contact hole formed by removing a portion of the insulating structure IL. In addition, the second pixel electrode PE2 may be connected to the second transistor TR2 through a contact hole formed by removing a portion of the insulating structure IL. In addition, the third pixel electrode PE3 may be connected to the third transistor TR3 through a contact hole formed by removing a portion of the insulating structure IL.

In an embodiment, for example, each of the first pixel electrode PET, the second pixel electrode PE2, and the third pixel electrode PE3 may include a metal, an alloy, a metal nitride, a conductive metal oxide, a transparent conductive material, or the like. These materials may be used alone or in combination with each other. In an embodiment, for example, each of the first pixel electrode PET, the second pixel electrode PE2, and the third pixel electrode PE3 may operate as an anode. The first pixel electrode PET may be referred to as a first electrode. In addition, the second pixel electrode PE2 may be referred to as a second electrode.

The first pixel defining layer PDL1 and the second pixel defining layer PDL2 may be disposed on the insulating structure IL, the first pixel electrode PET, the second pixel electrode PE2, and the third pixel electrode PE3. Specifically, the first pixel defining layer PDL1 may overlap the first non-light emitting area NLA1. In addition, the second pixel defining layer PDL2 may overlap the second non-light emitting area NLA2.

Each of the first pixel defining layer PDL1 and the second pixel defining layer PDL2 may include an organic material and/or an inorganic material. In an embodiment, for example, each of the first pixel defining layer PDL1 and the second pixel defining layer PDL2 may include a photoresist, polyacrylic resin, polyimide resin, polyamide resin, siloxane resin, acrylic resin, epoxy resin, or the like. These materials may be used alone or in combination with each other.

In an embodiment, the first hole auxiliary layer HTL1, the second hole auxiliary layer HTL2, and the third hole auxiliary layer HTL3 may be disposed on the first pixel electrode PE1, the second pixel electrode PE2, and the third pixel electrode PE3, respectively. In an embodiment, for example, each of the first hole auxiliary layer HTL1, the second hole auxiliary layer HTL2, and the third hole auxiliary layer HTL3 may include a hole injection layer and/or a hole transport layer.

However, the present disclosure is not limited thereto. In another embodiment, for example, each of the first hole auxiliary layer HTL1, the second hole auxiliary layer HTL2, and the third hole auxiliary layer HTL3 may further include a buffer layer or an electron blocking layer.

The buffer layer may increase light emission efficiency by compensating an optical resonance distance according to a wavelength of light emitted from each of the first light emitting layer EML1, the second light emitting layer EML2, and the third light emitting layer EML3. In addition, the electron blocking layer may prevent electron injection from each of the first electron auxiliary layer ETL1, the second electron auxiliary layer ETL2, and the third electron auxiliary layer ETL3.

The first light emitting layer EML1, the second light emitting layer EML2, and the third light emitting layer EML3 may be disposed on the first hole auxiliary layer HTL1, the second hole auxiliary layer HTL2, and the third hole auxiliary layer HTL3, respectively. The first light emitting layer EML1, the second light emitting layer EML2, and the third light emitting layer EML3 may include the first quantum dots QD1, the second quantum dots QD2, and the third quantum dots QD3, respectively. Absorption wavelength and emission wavelength of each of the first quantum dots QD1, the second quantum dots QD2, and the third quantum dots QD3 may be adjusted by adjusting composition and/or size of each of the first quantum dots QD1, the second quantum dots QD2, and the third quantum dots QD3.

In an embodiment, each of the first quantum dots QD1, the second quantum dots QD2, and the third quantum dots QD3 may include a group II-VI compound, a group III-V compound, a group IV-VI compound, a group IV element, or a group IV compound, or the like. These materials may be used alone or in combination with each other.

In an embodiment, for example, the group II-VI compound may include CdSe, CdTe, ZnS, ZnSe, ZnTe, ZnO, HgS, HgSe, or the like. The group III-V compound may include GaN, GaP, GaAs, GaSb, AlN, AlP, or the like. The group IV-VI compound may include SnS, SnSe, SnTe, PbS PbSe, or the like. The group IV element may include Si, Ge, or the like. The group IV compound may include SiC, SiGe, or the like.

The first electron auxiliary layer ETL1, the second electron auxiliary layer ETL2, and the third electron auxiliary layer ETL3 may be disposed on the first light emitting layer EML1, the second light emitting layer EML2, and the third light emitting layer EML3, respectively. Each of the first electron auxiliary layer ETL1, the second electron auxiliary layer ETL2, and the third electron auxiliary layer ETL3 may include an electron transport layer and/or an electron injection layer.

However, the present disclosure is not limited thereto. In another embodiment, for example, each of the first electron auxiliary layer ETL1, the second electron auxiliary layer ETL2, and the third electron auxiliary layer ETL3 may further include a hole blocking layer. The hole blocking layer may prevent hole injection from the first hole auxiliary layer HTL1, the second hole auxiliary layer HTL2, and the third hole auxiliary layer HTL3.

In an embodiment, the first electron auxiliary layer ETL1, the second electron auxiliary layer ETL2, and the third electron auxiliary layer ETL3 may include the first nanoparticles NP1, the second nanoparticles NP2, and the third nanoparticles NP3, respectively. In an embodiment, each of the first nanoparticles NPT, the second nanoparticles NP2, and the third nanoparticles NP3 may include a metal oxide. In an embodiment, for example, the metal oxide may include zinc, magnesium, or the like. These materials may be used alone or in combination with each other.

The common electrode CE may be disposed on the first electron auxiliary layer ETL1, the second electron auxiliary layer ETL2, and the third electron auxiliary layer ETL3, the first pixel defining layer PDL1, and the second pixel defining layer PDL2. In an embodiment, the common electrode CE may be continuously disposed over the first pixel area PXT, the first non-light emitting area NLA1, the second pixel area PX2, the second non-light emitting area NLA2, and the third pixel area PX3.

However, the present disclosure is not limited thereto, and in another embodiment, the common electrode CE may cover only a portion of each of the first electron auxiliary layer ETL1, the second electron auxiliary layer ETL2, and the third electron auxiliary layer ETL3. That is, the common electrode CE may not cover the first pixel defining layer PDL1 and the second pixel defining layer PDL2.

In an embodiment, for example, the common electrode CE may include a metal, an alloy, a metal nitride, a conductive metal oxide, a transparent conductive material, or the like. These materials may be used alone or in combination with each other. In an embodiment, for example, the common electrode CE may operate as a cathode. The common electrode CE may be referred to as a third electrode.

In an embodiment, the common electrode CE may define a first opening OPT in a portion overlapping the first non-light emitting area NLA1. In addition, the common electrode CE may define a second opening OP2 in a portion overlapping the second non-light emitting area NLA2. However, the present disclosure is not limited thereto. In another embodiment, for example, the common electrode CE may define two or more openings in a portion overlapping the first non-light emitting area NLA1. In addition, the common electrode CE may define two or more openings in a portion overlapping the second non-light emitting area NLA2.

In an embodiment, each of the first opening OP1 and the second opening OP2 may have a triangular shape in a cross-section. However, the present disclosure is not limited thereto. In another embodiment, for example, each of the first opening OP1 and the second opening OP2 may have a polygonal, circular, or semicircular shape in a cross-section.

In an embodiment, a distance W1 between the first opening OP1 and the first pixel area PX1 may be the same as a distance W2 between the first opening OP1 and the second pixel area PX2. In addition, a distance W3 between the second opening OP2 and the second pixel area PX2 may be the same as a distance W4 between the second opening OP2 and the third pixel area PX3.

However, the present disclosure is not limited to this, and in another embodiment, the distance W1 between the first opening OP1 and the first pixel area PX1 may be different from the distance W2 between the first opening OP1 and the second pixel area PX2. In addition, the distance W3 between the second opening OP2 and the second pixel area PX2 may be different from the distance W4 between the second opening OP2 and the third pixel area PX3.

Each of the first opening OP1 and the second opening OP2 may penetrate the common electrode CE. Specifically, the first opening OP1 may penetrate from an upper surface of the common electrode CE to an upper surface of the first pixel defining layer PDL1. In addition, the second opening OP2 may penetrate from the upper surface of the common electrode CE to an upper surface of the second pixel defining layer PDL2.

However, the present disclosure is not limited thereto, and in another embodiment, each of the first opening OP1 and the second opening OP2 may have a form in which only a portion of the common electrode CE is removed from the upper surface of the common electrode CE.

The first resin layer RS1 and the second resin layer RS2 may fill the first opening OP1 and the second opening OP2, respectively. In an embodiment, each of the first resin layer RS1 and the second resin layer RS2 may include an organic acid, an inorganic acid, or a peroxide. These materials may be used alone or in combination with each other.

In an embodiment, for example, the organic acid may include acrylic acid, acetic acid, formic acid, propionic acid, butyric acid, isobutyric acid, valeric acid, ethyl methyl acetic acid, trimethyl acetic acid, succinic acid, adipic acid, citric acid, oxalic acid, lactic acid, tartaric acid, malic acid, ascorbic acid, malonic acid, or the like. These materials may be used alone or in combination with each other. However, the present disclosure is not limited thereto, and the organic acid may include other kinds of materials.

In an embodiment, for example, the inorganic acid may include sulfuric acid, hydrochloric acid, nitric acid, or the like. These materials may be used alone or in combination with each other.

In an embodiment, for example, the peroxide may contain hydrogen peroxide water. However, the present disclosure is not limited thereto, and the peroxide may include other types of materials.

As mentioned above, each of the first light emitting layer EML1, the second light emitting layer EML2, and the third light emitting layer EML3 may include the first quantum dots QD1, the second quantum dots QD2, and the third quantum dots QD3, respectively. In addition, each of the first electron auxiliary layer ETL1, the second electron auxiliary layer ETL2, and the third electron auxiliary layer ETL3 may include the first nanoparticles NP1, the second nanoparticles NP2, and the third nanoparticles NP3. In an embodiment, each of the first nanoparticles NP1, the second nanoparticles NP2, and the third nanoparticles NP3 may include a metal oxide. In an embodiment, the first resin layer RS1 and the second resin layer RS2 supplying acid may be applied on the common electrode CE. Accordingly, a light emission efficiency and life of the display device DD may be effectively improved. This can be referred to as a positive aging effect.

A common electrode according to a comparative example may not define openings therein. In this case, resin layers may be applied on the common electrode. The resin layers may be injected from an edge of the display device. In this case, the resin layers may not reach a central portion of the display device. Accordingly, the resin layers may not be uniformly applied over the display device. Accordingly, the positive aging effect may not be uniform over the display device.

The common electrode CE according to an embodiment may define a first opening OP1 and a second opening OP2 therein. In addition, the first resin layer RS1 and the second resin layer RS2 may fill the first opening OP1 and the second opening OP2, respectively. That is, the resin layers may be well applied (or fixed) to a surface of the common electrode CE through openings including the first opening OP1 and the second opening OP2. Accordingly, the resin layers may relatively uniformly reach an entire area including the center of the display device DD. Accordingly, the positive aging effect may be relatively uniform over the display device DD.

The encapsulation layer TFE may be disposed on the common electrode CE. The encapsulation layer TFE may include at least one inorganic encapsulation layer and at least one organic encapsulation layer. In an embodiment, for example, the inorganic encapsulation layer may include silicon oxide, silicon nitride, silicon oxynitride, or the like, and the organic encapsulation layer may include a polymer cured product such as polyacrylate.

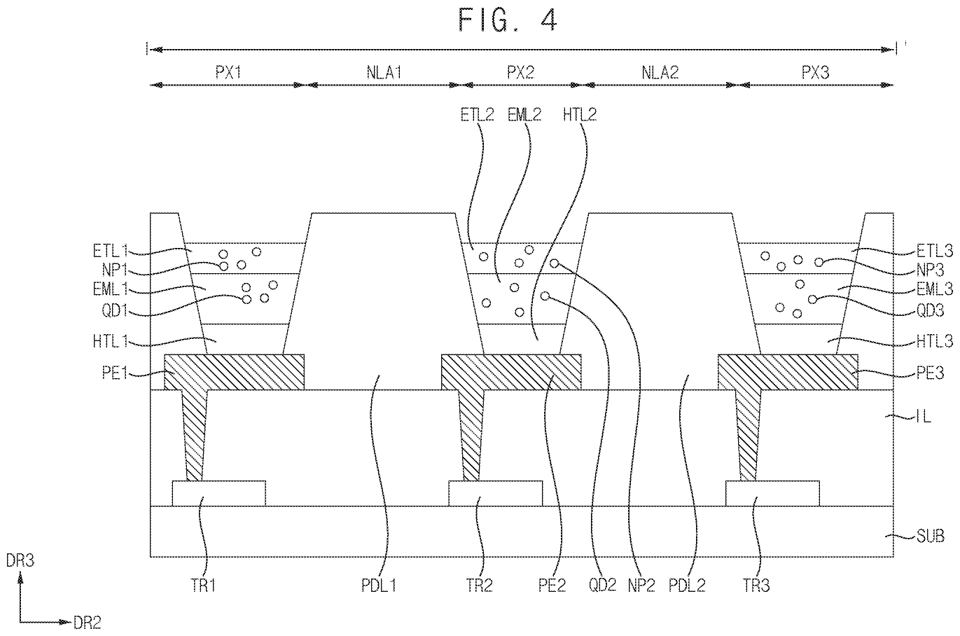

FIGS. 4, 5, 6, and 7 are schematic cross-sectional views illustrating a method of manufacturing the display device of FIG. 2.

Referring to FIG. 4, the first transistor TR1, the second transistor TR2, and the third transistor TR3 may be formed on the substrate SUB. In an embodiment, for example, the substrate SUB may be formed of a transparent resin substrate. In addition, each of the first transistor TR1, the second transistor TR2, and the third transistor TR3 may be formed using amorphous silicon, crystalline silicon, or metal oxide semiconductor.

In addition, the insulating structure IL may be formed on the substrate SUB. The insulating structure IL may be formed to cover the first transistor TR1, the second transistor TR2, and the third transistor TR3. In an embodiment, for example, the insulating structure IL may include at least one inorganic insulating layer and at least one organic insulating layer.

The first pixel electrode PET, the second pixel electrode PE2, and the third pixel electrode PE3 may be formed on the insulating structure IL. The first pixel electrode PET may be formed to overlap the first pixel area PX1. In addition, the second pixel electrode PE2 may be formed to overlap the second pixel area PX2. In addition, the third pixel electrode PE3 may be formed to overlap the third pixel area PX3.

The first pixel electrode PET may be connected to the first transistor TR1 through a contact hole formed by removing a portion of the insulating structure IL. In addition, the second pixel electrode PE2 may be connected to the second transistor TR2 through a contact hole formed by removing a portion of the insulating structure IL. In addition, the third pixel electrode PE3 may be connected to the third transistor TR3 through a contact hole formed by removing a portion of the insulating structure IL.

In an embodiment, for example, each of the first pixel electrode PET, the second pixel electrode PE2, and the third pixel electrode PE3 may be formed using a metal, an alloy, a metal nitride, a conductive metal nitride, a transparent conductive material, or the like.

These materials may be used alone or in combination with each other.

The first pixel defining layer PDL1 and the second pixel defining layer PDL2 may be formed on the insulating structure IL, the first pixel electrode PET, the second pixel electrode PE2, and the third pixel electrode PE3. The first pixel defining layer PDL1 may be formed to overlap the first non-light emitting area NLA1. In addition, the second pixel defining layer PDL2 may be formed to overlap the second non-light emitting area NLA2. Each of the first pixel defining layer PDL1 and the second pixel defining layer PDL2 may be formed using an organic material and/or an inorganic material.

In an embodiment, the first hole auxiliary layer HTL1, the second hole auxiliary layer HTL2, and the third hole auxiliary layer HTL3 may be formed on the first pixel electrode PET, the second pixel electrode PE2, and the third pixel electrode PE3, respectively.

In an embodiment, for example, each of the first hole auxiliary layer HTL1, the second hole auxiliary layer HTL2, and the third hole auxiliary layer HTL3 may include a poly(9,9-dioxyl-fluorene-co-N-(4-butylphenyl)-diphenylamine), poly(C₆-C₄₀) arylamine, poly(N-vinylcarbazole), polyaniline, polypyrrole, p-type metal oxide (e.g., NiO, WO₃, or the like.), graphene oxide, or the like. These materials may be used alone or in combination with each other.

The first light emitting layer EML1, the second light emitting layer EML2, and the third light emitting layer EML3 may be formed on the first hole auxiliary layer HTL1, the second hole auxiliary layer HTL2, and the third hole auxiliary layer HTL3, respectively. In an embodiment, for example, each of the first light emitting layer EML1, the second light emitting layer EML2, and the third light emitting layer EML3 may be formed using a low molecular organic compound and/or a polymer organic compound.

In an embodiment, the first light emitting layer EML1, the second light emitting layer EML2, and the third light emitting layer EML3 may include the first quantum dots QD1, the second quantum dots QD2, and the third quantum dots QD3, respectively, each of the first quantum dots QD1, the second quantum dots QD2, and the third quantum dots QD3 may include a group II-VI compound, a group III-V compound, a group IV-VI compound, a group IV element, or a group IV compound, or the like. These materials may be used alone or in combination with each other.

The first electron auxiliary layer ETL1, the second electron auxiliary layer ETL2, and the third electron auxiliary layer ETL3 may be formed on the first light emitting layer EML1, the second light emitting layer EML2, and the third light emitting layer EML3, respectively. the first electron auxiliary layer ETL1, the second electron auxiliary layer ETL2, and the third electron auxiliary layer ETL3 may include the first nanoparticles NP1, the second nanoparticles NP2, and the third nanoparticles NP3, respectively. each of the first nanoparticles NP1, the second nanoparticles NP2, and the third nanoparticles NP3 may include a metal oxide. In an embodiment, for example, the metal oxide may include zinc, magnesium, or the like. These materials may be used alone or in combination with each other.

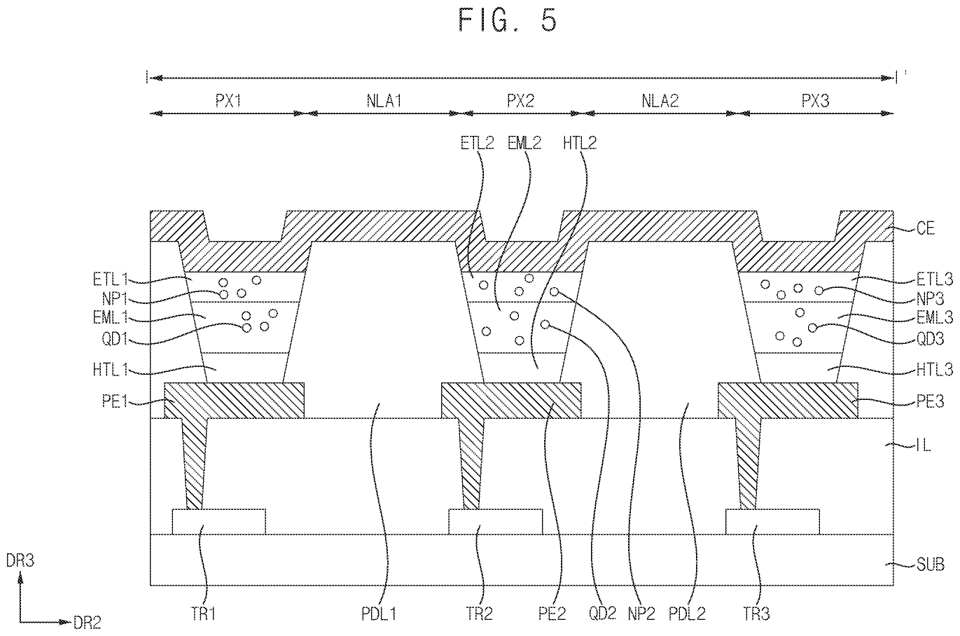

Referring to FIG. 5, the common electrode CE may be formed on the first electron auxiliary layer ETL1, the second electron auxiliary layer ETL2, the third electron auxiliary layer ETL3, the first pixel defining layer PDL1, and the second pixel defining layer PDL2. In an embodiment, the common electrode CE may include a metal, an alloy, a metal nitride, a conductive metal oxide, a transparent conductive material, or the like. These materials may be used alone or in combination with each other.

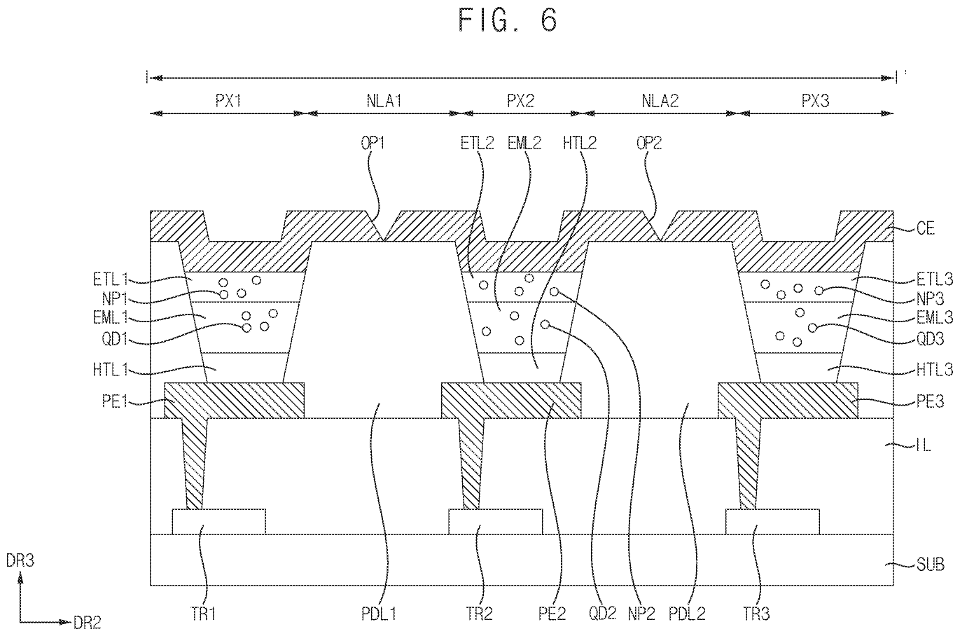

Referring to FIG. 6, the first opening OP1 may be formed in a portion of the common electrode CE overlapping the first non-light emitting area NLA1. In addition, a second opening OP2 may be formed in a portion of the common electrode CE overlapping the second non-light emitting area NLA2. In an embodiment, the first opening OP1 and the second opening OP2 may be formed through a laser drilling process. However, the present disclosure is not limited to this, and in another embodiment, the first opening OP1 and the second opening OP2 may be formed using a stamper.

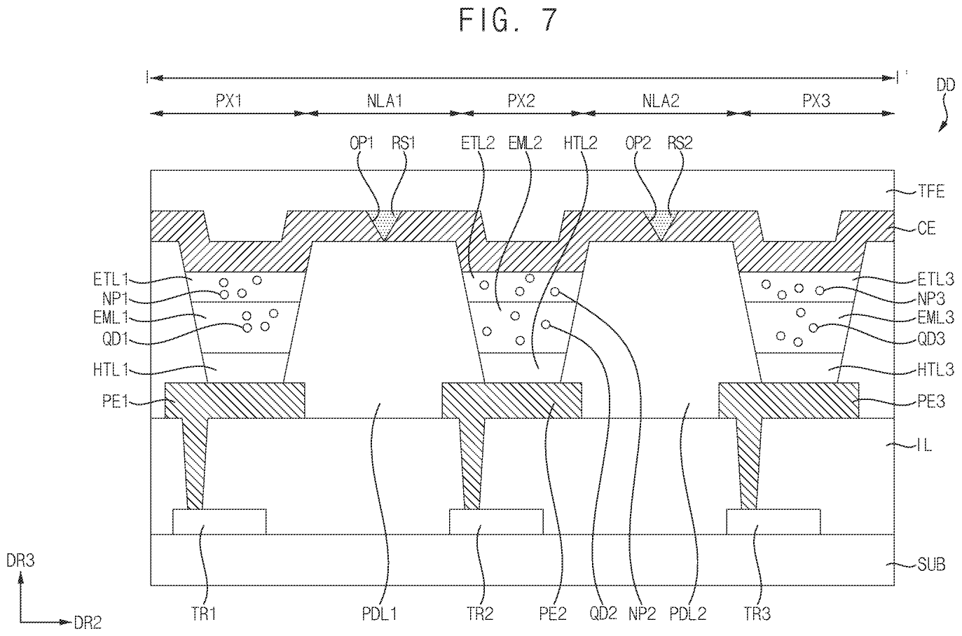

Referring to FIG. 7, the first resin layer RS1 may fill the first opening OP1. In addition, the second resin layer RS2 may fill the second opening OP2. In an embodiment, each of the first resin layer RS1 and the second resin layer RS2 may include an organic acid, an inorganic acid, or a peroxide. These materials may be used alone or in combination with each other.

In an embodiment, for example, the organic acid may include acrylic acid, acetic acid, formic acid, propionic acid, butyric acid, isobutyric acid, valeric acid, ethyl methyl acetic acid, trimethyl acetic acid, succinic acid, adipic acid, citric acid, oxalic acid, lactic acid, tartaric acid, malic acid, ascorbic acid, malonic acid, or the like. These materials may be used alone or in combination with each other. However, the present disclosure is not limited thereto, and the organic acid may include other kinds of materials.

In an embodiment, for example, the inorganic acid may include sulfuric acid, hydrochloric acid, nitric acid, or the like. These materials may be used alone or in combination with each other.

In an embodiment, for example, the peroxide may contain hydrogen peroxide water. However, the present disclosure is not limited thereto, and the peroxide may include other types of materials.

The encapsulation layer TFE may be formed on the common electrode CE. The encapsulation layer TFE may include at least one inorganic encapsulation layer and at least one organic encapsulation layer. In an embodiment, for example, the inorganic encapsulation layer may include silicon oxide, silicon nitride, silicon oxynitride, or the like, and the organic encapsulation layer may include a polymer cured product such as polyacrylate.

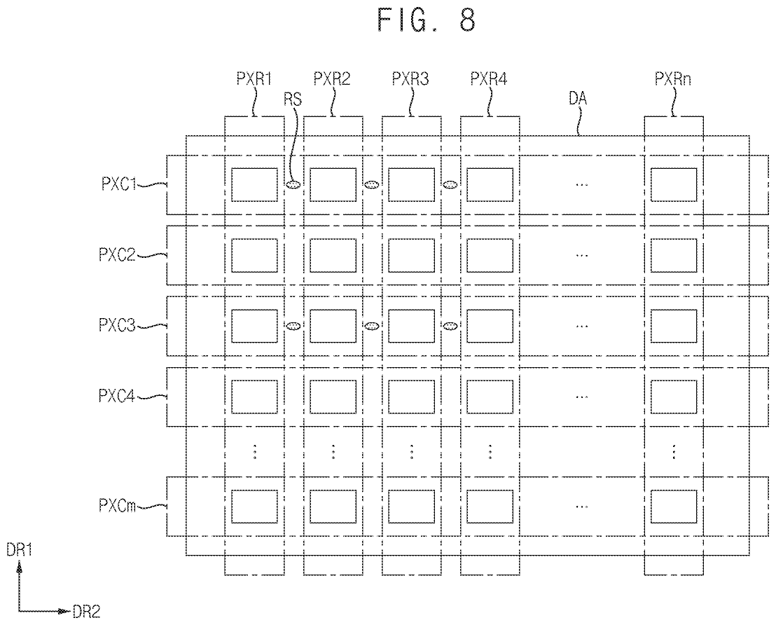

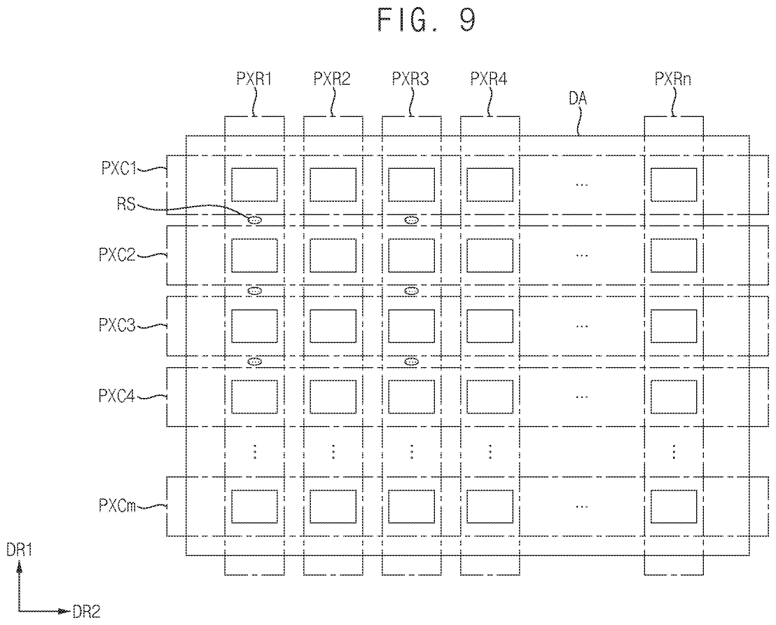

FIGS. 8 and 9 are schematic plan views illustrating the display device of FIG. 1.

Referring to FIG. 8, the display area DA of the display device (e.g., the display device DD of FIG. 1) may include a plurality of pixel areas. The plurality of pixel areas may be arranged in m rows and n columns. That is, the plurality of pixel areas may have m pixel rows PXC1, PXC2, PXC3, PXC4, . . . , PXCm or n pixel columns PXR1, PXR2, PXR3, PXR4, . . . , PXRn.

In an embodiment, resin layers RS may be disposed between two adjacent pixel areas of the plurality of pixel areas disposed along odd pixel rows (e.g., the first pixel row PXC1, the third pixel row PXC3). Specifically, a plurality of openings may be defined between two adjacent pixel areas of the plurality of pixel areas arranged along the odd pixel rows, respectively. In addition, the resin layers RS may fill each of the plurality of openings.

However, the present disclosure is not limited thereto. In another embodiment, for example, the resin layers RS may be disposed between two adjacent pixel areas of the plurality of pixel areas arranged along pixel rows corresponding to multiple of 4 (e.g., the fourth pixel row PXC4). Specifically, a plurality of openings may be defined between two adjacent pixel areas of the plurality of pixel areas arranged along the pixel rows corresponding to the multiple of 4, respectively. In addition, the resin layers RS may fill the plurality of openings, respectively.

Referring to FIG. 9, in another embodiment, the resin layers RS may be disposed between two adjacent pixel areas of the plurality of pixel areas disposed along odd pixel columns (e.g., the first pixel column PXR1, the third pixel column PXR3). Specifically, a plurality of openings may be defined between two adjacent pixel areas of the plurality of pixel areas arranged along the odd pixel columns, respectively. In addition, the resin layers RS may fill each of the plurality of openings.

However, the present disclosure is not limited thereto. In another embodiment, for example, the resin layers RS may be disposed between two adjacent pixel areas of the plurality of pixel areas arranged along pixel columns corresponding to multiple of 4 (e.g., the fourth pixel column PXR4). Specifically, a plurality of openings may be defined between two adjacent pixel areas of the plurality of pixel areas arranged along the pixel columns corresponding to the multiple of 4, respectively. In addition, the resin layers RS may fill the plurality of openings, respectively.

That is, positions of the resin layers RS and spacing of two adjacent resin layers RS of the resin layers RS may be adjusted according to purpose of the present disclosure.

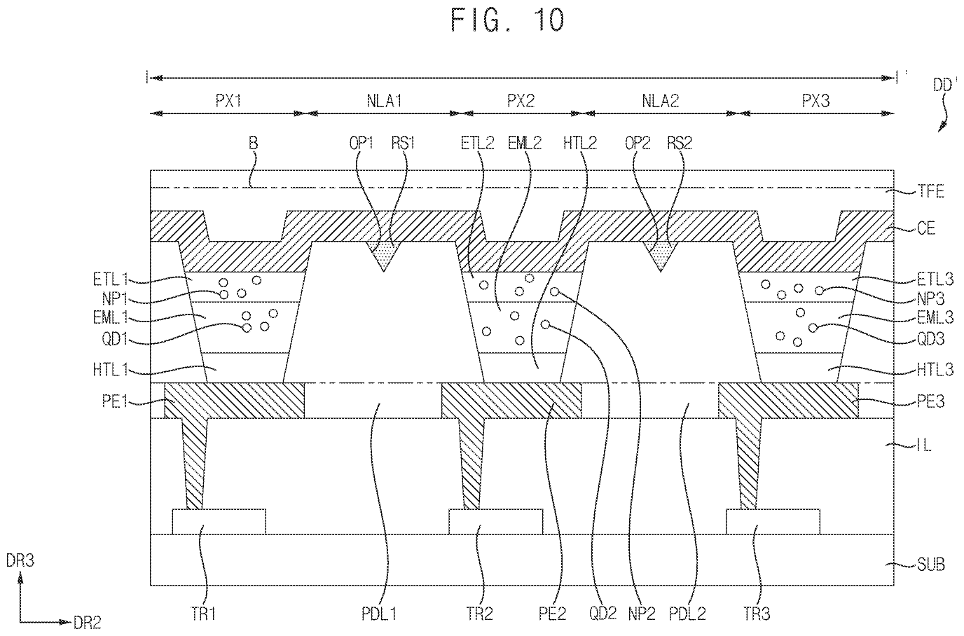

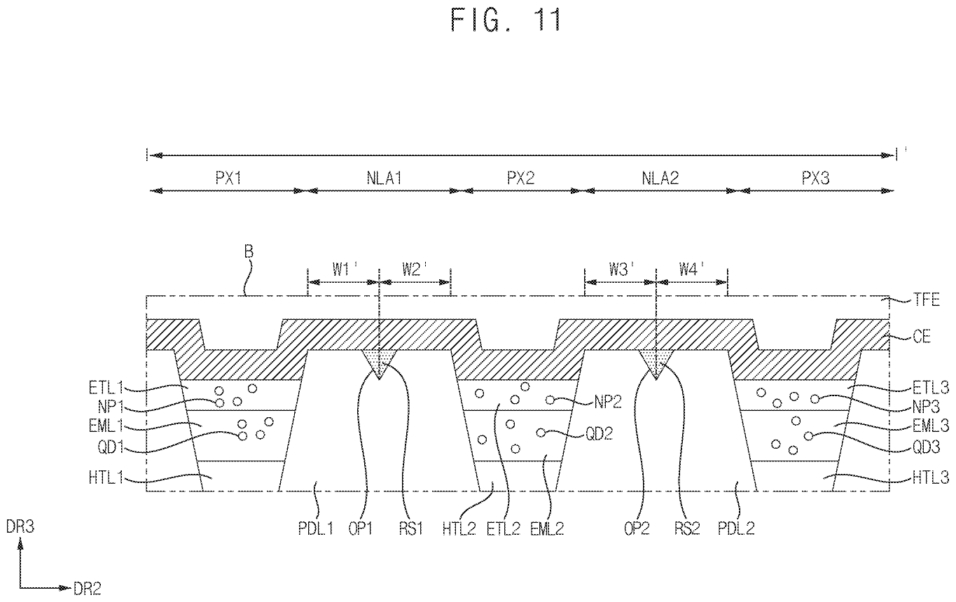

FIG. 10 is a schematic cross-sectional view illustrating a display device according to another embodiment. FIG. 11 is a schematic enlarged cross-sectional view illustrating an area B of FIG. 10.

In describing a display device DD′ of FIG. 10, same signs may be assigned to components that are practically the same as the display device DD of FIG. 2, and detailed description thereof may be omitted.

The display device DD′ of FIG. 10 may have substantially the same configuration as the display device DD of FIG. 2, except for positions of the first opening OP1, the first resin layer RS1, the second opening OP2, and the second resin layer RS2.

Referring to FIGS. 10 and 11, the display device DD′ according to another embodiment may include a substrate SUB, an insulating structure IL, a first transistor TR1, a second transistor TR2, a third transistors TR3, a first pixel electrode PE1, a second pixel electrode PE2, a third pixel electrode PE3, a first hole auxiliary layer HTL1, a second hole auxiliary layer HTL2, a third hole auxiliary layer HTL3, a first light emitting layer EML1, a second light emitting layer EML2, a third light emitting layer EML3, a first electron auxiliary layer ETL1, a second electron auxiliary layer ELT2, a third electron auxiliary layer ETL3, first quantum dots QD1, second quantum dots QD2, third quantum dots QD3, first nanoparticles NP1, second nanoparticles NP2, third nanoparticles NP3, a common electrode CE, a first resin layer RS1, and a second resin layer RS2, a first pixel defining layer PDL1, and a second pixel defining layer PDL2.

The first pixel defining layer PDL1 may define a first opening OP1. In addition, the second pixel defining layer PDL2 may define a second opening OP2. However, the present disclosure is not limited thereto. In another embodiment, for example, each of the first pixel defining layer PDL1 and the second pixel defining layer PDL2 may define two or more openings therein.

The first opening OP1 may have a shape in which a portion of the first pixel defining layer PDL1 is removed. Specifically, the first opening OP1 may have a form in which a portion of the first pixel defining layer PDL1 is removed from an upper surface of the first pixel defining layer PDL1. In addition, the second opening OP2 may have a shape in which a portion of the second pixel defining layer PDL2 is removed. Specifically, the second opening OP2 may have a form in which a portion of the second pixel defining layer PDL2 is removed from an upper surface of the second pixel defining layer PDL2.

In an embodiment, each of the first opening OP1 and the second opening OP2 may have a triangular shape in cross-section. However, the present disclosure is not limited thereto. In another embodiment, for example, each of the first opening OP1 and the second opening OP2 may have a polygonal, circular, or semicircular shape in a cross-section.

In an embodiment, a distance W1′ between the first opening OP1 and the first pixel area PX1 may be the same as a distance W2′ between the first opening OP1 and the second pixel area PX2. In addition, a distance W3′ between the second opening OP2 and the second pixel area PX2 may be the same as a distance W4′ between the second opening OP2 and the third pixel area PX3.

However, the present disclosure is not limited to this, and in another embodiment, the distance W1′ between the first opening OP1 and the first pixel area PX1 may be different from the distance W2′ between the first opening OP1 and the second pixel area PX2. In addition, the distance W3′ between the second opening OP2 and the second pixel area PX2 may be different from the distance W4′ between the second opening OP2 and the third pixel area PX3.

The first resin layer RS1 and the second resin layer RS2 may fill the first opening OP1 and the second opening OP2, respectively.

The common electrode CE may be disposed on the first electron auxiliary layer ETL1, the second electron auxiliary layer ETL2, and the third electron auxiliary layer ETL3, the first pixel defining layer PDL1, and the second pixel defining layer PDL2. In an embodiment, the common electrode CE may be continuously disposed over the first pixel area PX1, the first non-light emitting area NLA1, the second pixel area PX2, the second non-light emitting area NLA2, and the third pixel area PX3.

However, the present disclosure is not limited thereto, and in another embodiment, the common electrode CE may cover only a portion of each of the first electron auxiliary layer ETL1, the second electron auxiliary layer ETL2, and the third electron auxiliary layer ETL3. That is, the common electrode CE may not cover the first pixel defining layer PDL1 and the second pixel defining layer PDL2.

The present disclosure can be applied to various display devices. In an embodiment, for example, the present disclosure is applicable to various display devices such as display devices for vehicles, ships and aircraft, portable communication devices, display devices for exhibition or information transmission, medical display devices, or the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate including a first pixel area, a second pixel area adjacent to the first pixel area, and a non-light emitting area surrounding the first pixel area and the second pixel area;
a first electrode disposed in a portion overlapping the first pixel area on the substrate;
a second electrode disposed in a portion overlapping the second pixel area on the substrate;
a third electrode disposed on the first electrode and the second electrode and defining at least one opening in a portion overlapping the non-light emitting area; and
a resin layer filling the opening.

2. The display device of claim 1, wherein the resin layer includes at least one selected from a group consisting of organic acid, inorganic acid and peroxide.

3. The display device of claim 2, wherein the organic acid includes at least one selected from a group consisting of acrylic acid, acetic acid, formic acid, propionic acid, butyric acid, isobutyric acid, valeric acid, ethyl methyl acetic acid, trimethyl acetic acid, succinic acid, adipic acid, citric acid, oxalic acid, lactic acid, tartaric acid, malic acid, ascorbic acid, and malonic acid.

4. The display device of claim 2, wherein the inorganic acid includes at least one selected from a group consisting of sulfuric acid, hydrochloric acid, and nitric acid.

5. The display device of claim 1, wherein the third electrode is continuously disposed over the first pixel area, the second pixel area, and the non-light emitting area.

6. The display device of claim 5, further comprising:
a first light emitting layer disposed between the first electrode and the third electrode; and
a second light emitting layer disposed between the second electrode and the third electrode.

7. The display device of claim 6, wherein each of the first light emitting layer and the second light emitting layer includes a quantum dot.

8. The display device of claim 7, further comprising:
a first electron auxiliary layer disposed between the first light emitting layer and the third electrode; and
a second electron auxiliary layer disposed between the second light emitting layer and the third electrode.

9. The display device of claim 8, wherein each of the first electron auxiliary layer and the second electron auxiliary layer includes a plurality of nanoparticles.

10. The display device of claim 9, wherein each of the plurality of nanoparticles includes a metal oxide.

11. A display device comprising:
a substrate including a first pixel area, a second pixel area adjacent to the first pixel area, and a non-light emitting area surrounding the first pixel area and the second pixel area;
a first electrode disposed in a portion overlapping the first pixel area on the substrate;
a second electrode disposed in a portion overlapping the second pixel area on the substrate;
a pixel defining layer disposed in a portion overlapping the non-light emitting area on the substrate and defining at least one opening therein; and
a resin layer filling the opening.

12. The display device of claim 11, wherein the resin layer includes at least one selected from a group consisting of organic acid, inorganic acid and peroxide.

13. The display device of claim 12, wherein the organic acid includes at least one selected from a group consisting of acrylic acid, acetic acid, formic acid, propionic acid, butyric acid, isobutyric acid, valeric acid, ethyl methyl acetic acid, trimethyl acetic acid, succinic acid, adipic acid, citric acid, oxalic acid, lactic acid, tartaric acid, malic acid, ascorbic acid, and malonic acid.

14. The display device of claim 12, wherein the inorganic acid includes at least one selected from a group consisting of sulfuric acid, hydrochloric acid, and nitric acid.

15. The display device of claim 11, further comprising:
a third electrode disposed on the first electrode, the second electrode, and the pixel defining layer.

16. The display device of claim 15, further comprising:
a first light emitting layer disposed between the first electrode and the third electrode; and
a second light emitting layer disposed between the second electrode and the third electrode.

17. The display device of claim 16, wherein each of the first light emitting layer and the second light emitting layer includes a quantum dot.

18. The display device of claim 17, further comprising:
a first electron auxiliary layer disposed between the first light emitting layer and the third electrode; and
a second electron auxiliary layer disposed between the second light emitting layer and the third electrode.

19. The display device of claim 18, wherein each of the first electron auxiliary layer and the second electron auxiliary layer includes a plurality of nanoparticles.

20. The display device of claim 19, wherein each of the plurality of nanoparticles includes a metal oxide.
